(19) United States
(12) Patent Application Publication
(10) Pub. No.: US 2024/0413233 A1
(43) Pub. Date: Dec. 12, 2024

(54) GALLIUM NITRIDE SEMICONDUCTOR DEVICE

(71) Applicant: UNITED MICROELECTRONICS CORP., Hsin-Chu City (TW)

(72) Inventors: Yi-Chuan Chen, Tainan City (TW); Po-Wei Wang, Tainan City (TW); Huan-Chi Ma, Tainan City (TW); Chien-Wen Yu, Kaohsiung City (TW)

(73) Assignee: UNITED MICROELECTRONICS CORP., Hsin-Chu City (TW)

(21) Appl. No.: 18/221,863

(22) Filed: Jul. 13, 2023

(30) Foreign Application Priority Data
Jun. 8, 2023 (CN) 202310677890.9

(51) Int. Cl. H01L 29/778; H01L 21/02; H01L 23/29; H01L 23/31; H01L 29/20; H01L 29/40; H01L 29/47; H01L 29/66

(52) U.S. Cl. CPC H01L 29/7786; H01L 21/02178; H01L 23/291; H01L 23/3171; H01L 23/3192; H01L 29/2003; H01L 29/401; H01L 29/475; H01L 29/66462

(57) ABSTRACT

A GaN-based semiconductor device includes a substrate; a GaN channel layer disposed on the substrate; a AlGaN layer disposed on the GaN channel layer; a p-GaN gate layer disposed on the AlGaN layer; and a nitrogen-rich TiN hard mask layer disposed on the p-GaN gate layer. The nitrogen-rich TiN hard mask layer has a nitrogen-to-titanium (N/Ti) ratio that is greater than 1.0. A gate electrode layer is disposed on the nitrogen-rich TiN hard mask layer.

### BACKGROUND OF THE INVENTION

### 1. Field of the Invention

The invention relates to the field of semiconductor technology, in particular to an improved gallium nitride (GaN) high-electron mobility transistor (HEMT) and a manufacturing method thereof.

### 2. Description of the Prior Art

Owing to the high carrier density and high electron mobility of the two dimensional electron gas (2DEG), high electron mobility transistors (HEMTs) based on gallium nitride (GaN) are suitable devices for high power and high frequency applications. The presence of the 2DEG at the interface of AlGaN/GaN heterostructures makes HEMTs intrinsically normally-on devices. However, for power electronics applications, normally-off operation is desired for safety reasons and to simplify the driver circuitry.

GaN-based HEMTs with a p-GaN gate has been developed for normally-off operations and is commercially available today. However, the injected electrons may be captured by the traps in the depleted p-GaN gate layer and may therefore impact the reliability of the HEMT devices. Depending on the applied gate bias, the electron trapping process can play a key role for the reliability of the p-GaN HEMTs.

### SUMMARY OF THE INVENTION

It is one object of the present invention to provide an improved GaN-based high electron mobility transistor and its manufacturing method to solve the deficiencies or shortcomings of the prior art.

One aspect of the invention provides a GaN-based semiconductor device including a substrate; a GaN channel layer disposed on the substrate; a AlGaN layer disposed on the GaN channel layer; a p-GaN gate layer disposed on the AlGaN layer; a nitrogen-rich TiN hard mask layer disposed on the p-GaN gate layer, wherein the nitrogen-rich TiN hard mask layer has a nitrogen-to-titanium (N/Ti) ratio that is greater than 1.0; and a gate electrode layer disposed on the nitrogen-rich TiN hard mask layer.

According to some embodiments, the GaN-based semiconductor device further includes a buffer layer on the substrate, wherein the buffer layer is disposed between the substrate and the GaN channel layer.

According to some embodiments, the buffer layer comprises AlN or GaN and has a thickness of about 3-5 μm.

According to some embodiments, the GaN channel layer has a thickness of 200-400 nm.

According to some embodiments, the AlGaN layer has a thickness of 10-14 nm.

According to some embodiments, the p-GaN gate layer has a thickness of 60-100 nm.

According to some embodiments, the gate electrode layer comprises a TiN bottom layer, a AlCu middle layer, and a TiN top layer, wherein the TiN bottom layer is in direct contact with the nitrogen-rich TiN hard mask layer.

According to some embodiments, the N/Ti ratio of the nitrogen-rich TiN hard mask layer is equal to or greater than 1.04.

According to some embodiments, the GaN-based semiconductor device further includes a Al₂O₃ passivation layer covering a sidewall of the p-GaN gate layer, a sidewall of the nitrogen-rich TiN hard mask layer, and a top surface of the AlGaN layer.

According to some embodiments, the GaN-based semiconductor device further includes an insulating layer disposed on the Al₂O₃ passivation layer.

Another aspect of the invention provides a method for fabricating a GaN-based semiconductor device. A substrate is provided. A GaN channel layer is formed on the substrate. A AlGaN layer is formed on the GaN channel layer. A p-GaN gate layer is formed on the AlGaN layer. A nitrogen-rich TiN hard mask layer is formed on the p-GaN gate layer. The nitrogen-rich TiN hard mask layer has a nitrogen-to-titanium (N/Ti) ratio that is greater than 1.0. A gate electrode layer is formed on the nitrogen-rich TiN hard mask layer.

According to some embodiments, the method further includes the step of forming a buffer layer on the substrate, wherein the buffer layer is disposed between the substrate and the GaN channel layer.

According to some embodiments, the buffer layer comprises AlN or GaN and has a thickness of 3-5 μm.

According to some embodiments, the GaN channel layer has a thickness of 200-400 nm, the AlGaN layer has a thickness of 10-14 nm, and the p-GaN gate layer has a thickness of 60-100 nm.

According to some embodiments, the nitrogen-rich TiN hard mask layer is formed on the p-GaN gate layer by sputtering at a direct current (DC) power that is equal to or greater than 4000 W.

According to some embodiments, the nitrogen-rich TiN hard mask layer is formed on the p-GaN gate layer by sputtering at a DC power of 7500-8500 W.

According to some embodiments, the gate electrode layer comprises a TiN bottom layer, a AlCu middle layer, and a TiN top layer, wherein the TiN bottom layer is in direct contact with the nitrogen-rich TiN hard mask layer.

According to some embodiments, the N/Ti ratio of the nitrogen-rich TiN hard mask layer is equal to or greater than 1.04.

According to some embodiments, the method further includes the step of forming a Al₂O₃ passivation layer covering a sidewall of the p-GaN gate layer, a sidewall of the nitrogen-rich TiN hard mask layer, and a top surface of the AlGaN layer.

According to some embodiments, the method further includes the step of forming an insulating layer on the Al₂O₃ passivation layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, partial cross-sectional view of a GaN-based semiconductor device according to an embodiment of the present invention.

FIG. 2 is a flow chart of a fabrication method of a GaN-based semiconductor device.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

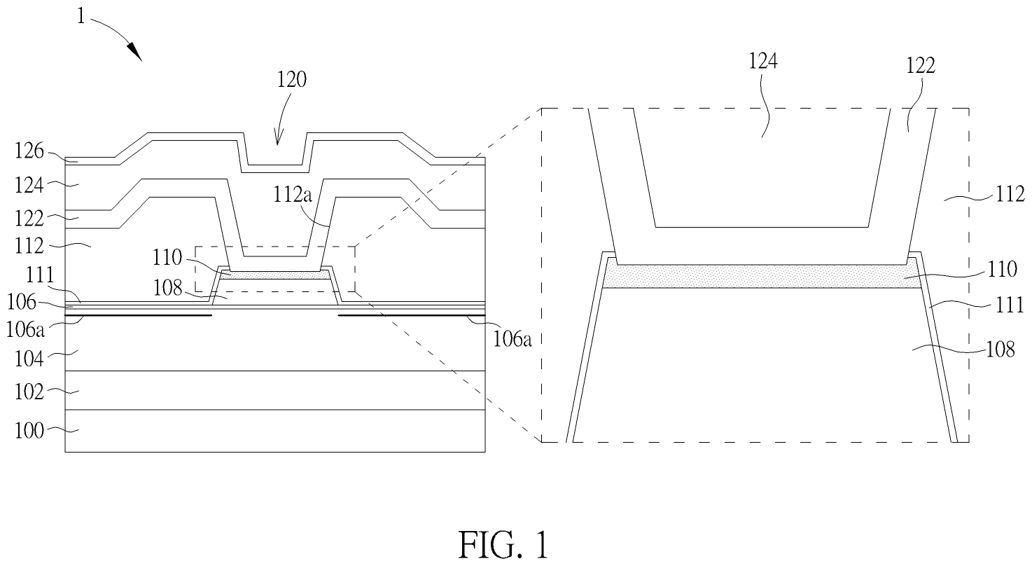

Please refer to FIG. 1, which is a partial cross-sectional view of a GaN-based semiconductor device according to an embodiment of the present invention. As shown in FIG. 1, a GaN-based semiconductor device 1 includes a substrate 100, for example, a silicon substrate with a (111) crystal plane, but not limited thereto. According to an embodiment of the present invention, the GaN-based semiconductor device 1 may be a p-GaN/AlGaN/GaN high electron mobility transistor (HEMT) device.

According to an embodiment of the present invention, a buffer layer 102 and a GaN channel layer 104 are formed on the substrate 100. The buffer layer 102 and the GaN channel layer 104 may be formed using an epitaxial process, such as a metal organic chemical vapor deposition (MOCVD) process or a molecular beam epitaxy (MBE) process, but not limited thereto.

According to an embodiment of the present invention, the buffer layer 102 may include AlN or GaN. According to an embodiment of the present invention, the thickness of the buffer layer 102 is, for example, 3-5 μm, but not limited thereto. According to an embodiment of the present invention, the thickness of the GaN channel layer 104 is, for example, 200-400 nm, but is not limited thereto.

According to an embodiment of the present invention, the GaN-based semiconductor device 1 further includes an AlGaN layer 106 disposed on the GaN channel layer 104. According to an embodiment of the present invention, the thickness of the AlGaN layer 106 is, for example, 10-14 nm, but not limited thereto.

According to an embodiment of the present invention, a two-dimensional electron gas (2DEG) 106a is formed at the interface between the AlGaN layer 106 and the GaN channel layer 104. The two-dimensional electron gas 106a is a very thin conductive layer with highly mobile and highly concentrated charge carriers.

According to an embodiment of the present invention, the GaN-based semiconductor device 1 further includes a patterned p-GaN gate layer 108 disposed on the AlGaN layer 106. According to an embodiment of the present invention, the p-GaN gate layer 108 can also be formed by an epitaxial process, for example, metal organic chemical vapor deposition process or molecular beam epitaxy, but not limited thereto. According to an embodiment of the present invention, the thickness of the p-GaN gate layer 108 is, for example, 60-100 nm, but not limited thereto.

According to an embodiment of the present invention, as shown in the partial enlarged view in FIG. 1, the GaN-based semiconductor device 1 further includes a patterned nitrogen-rich TiN hard mask layer 110 disposed on the p-GaN gate layer 108, wherein the nitrogen-to-titanium (N/Ti) ratio of the nitrogen-rich TiN hard mask layer 110 is greater than 1.0. According to an embodiment of the present invention, the N/Ti ratio of the entire nitrogen-rich TiN hard mask layer 110 is greater than 1.0. According to an embodiment of the present invention, for example, the N/Ti ratio of the nitrogen-rich TiN hard mask layer 110 may be between 1.0 and 1.2. According to an embodiment of the present invention, the N/Ti ratio of the nitrogen-rich TiN hard mask layer 110 is equal to or greater than 1.04.

According to an embodiment of the present invention, the nitrogen-rich TiN hard mask layer 110 may be formed by a physical vapor deposition (PVD) process such as sputtering, and the deposition conditions may include: DC power greater than 4000 W, for example, 7500 W-8500 W, argon/nitrogen (Ar/N₂) gas flow ratio of 30/100, and deposition at room temperature.

The present invention utilizes high DC power to form a nitrogen-rich TiN hard mask layer 110 to control the nitrogen-to-titanium ratio between 1.0 and 1.2, which can reduce the electron capture in the p-GaN gate layer during the operation of the GaN-based semiconductor device 1, thereby improving reliability of the GaN-based semiconductor device 1.

According to an embodiment of the present invention, the patterning of the p-GaN gate layer 108 and the nitrogen-rich TiN hard mask layer 110 can be accomplished by photolithography and dry etching.

According to an embodiment of the present invention, the GaN-based semiconductor device 1 further includes a gate electrode layer 120 disposed on the nitrogen-rich TiN hard mask layer 110. According to an embodiment of the present invention, for example, the gate electrode layer 120 may include a TiN bottom layer 120, an AlCu middle layer 124 and a TiN top layer 126. According to an embodiment of the present invention, the TiN bottom layer 122 is in direct contact with the nitrogen-rich TiN hard mask layer 110, and the TiN bottom layer 122 may slightly recess into the upper surface of the nitrogen-rich TiN hard mask layer 110.

According to an embodiment of the present invention, the GaN-based semiconductor device 1 further includes an Al₂O₃ passivation layer 111 covering the sidewalls of the p-GaN gate layer 108, the sidewalls of the nitrogen-rich TiN hard mask layer 110 and the top surface of the AlGaN layer 106.

According to an embodiment of the present invention, the GaN-based semiconductor device 1 further includes an insulating layer 112, such as a tetraethoxysilane (TEOS) silicon oxide layer, disposed on the Al₂O₃ passivation layer 111. According to an embodiment of the present invention, an opening 112a is formed in the insulating layer 112 and the Al₂O₃ passivation layer 111, and the gate electrode layer 120 is filled into the opening 112a, so that the gate electrode layer 120 is electrically connected to the nitrogen-rich TiN hard mask layer 110.

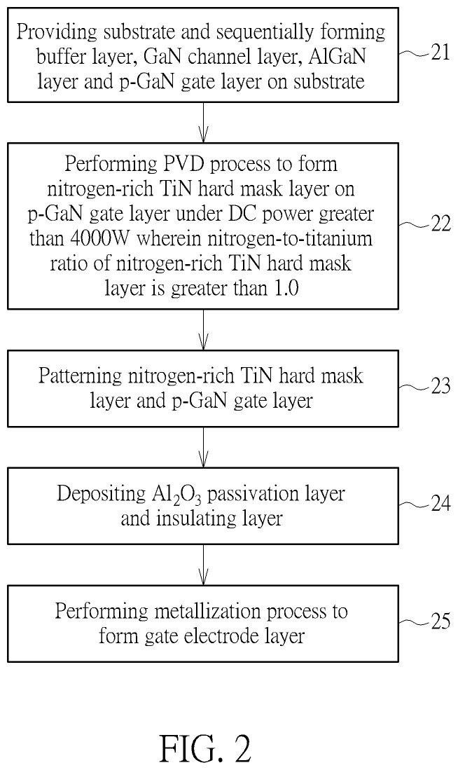

Please also refer to FIG. 2, which is a flow chart of the manufacturing method of the GaN-based semiconductor device 1, wherein like layers, regions or elements are still designated by like numeral numbers or labels. As shown in FIG. 2, in Step 21, a substrate 100 is provided. A buffer layer 102, a GaN channel layer 104, an AlGaN layer 106 and a p-GaN gate layer 108 are sequentially formed on the substrate 100.

According to an embodiment of the present invention, the buffer layer 102 may include AlN or GaN, and the thickness of the buffer layer 102 is, for example, 3-5 μm. According to an embodiment of the present invention, the thickness of the GaN channel layer 104 is, for example, 200-400 nm, the thickness of the AlGaN layer 106 is, for example, 10-14 nm, and the thickness of the p-GaN gate layer 108 is, for example, 60-100 nm.

In step 22, a physical vapor deposition (PVD) process is performed to form a nitrogen-rich TiN hard mask layer 110 on the p-GaN gate layer 108 under a DC power greater than 4000 W, for example, a DC power of 7500-8500 W, wherein the nitrogen-to-titanium ratio of the nitrogen-rich TiN hard mask layer 110 is greater than 1.0. According to an embodiment of the present invention, the nitrogen-to-titanium ratio of the nitrogen-rich TiN hard mask layer 110 is equal to or greater than 1.04.

In Step 23, a photolithography process and a dry etching process are performed to pattern the nitrogen-rich TiN hard mask layer 110 and the p-GaN gate layer 108.

In Step 24, an Al₂O₃ passivation layer 111 is deposited to conformally cover the top surface and sidewalls of the p-GaN gate layer 108, the sidewalls of the nitrogen-rich TiN hard mask layer 110 and the top surface of the AlGaN layer 106. Subsequently, an insulating layer 112 is formed on the Al₂O₃ passivation layer 111. According to an embodiment of the present invention, for example, the insulating layer 112 may include a tetraethoxysilane (TEOS) silicon oxide layer, but is not limited thereto.

In Step 25, a metallization process is performed. First, an opening 112a is formed in the insulating layer 112 and the Al₂O₃ passivation layer 111, so that the opening 112a exposes part of the upper surface of the nitrogen-rich TiN hard mask layer 110. A gate electrode layer 120 is then filled into the opening 112a and is electrically connected to the nitrogen-rich TiN hard mask layer 110.

According to an embodiment of the present invention, the gate electrode layer 120 may include a TiN bottom layer 122, an AlCu middle layer 124 and a TiN top layer 126, wherein the TiN bottom layer 122 is in direct contact with the nitrogen-rich TiN hard mask layer 110. Subsequent steps include fabrication of source and drain contacts, which are not described in detail because these steps are well-known techniques.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A GaN-based semiconductor device, comprising:
a substrate;
a GaN channel layer disposed on the substrate;
a AlGaN layer disposed on the GaN channel layer;
a p-GaN gate layer disposed on the AlGaN layer;
a nitrogen-rich TiN hard mask layer disposed on the p-GaN gate layer, wherein the nitrogen-rich TiN hard mask layer has a nitrogen-to-titanium (N/Ti) ratio that is greater than 1.0; and
a gate electrode layer disposed on the nitrogen-rich TiN hard mask layer.

2. The GaN-based semiconductor device according to claim 1 further comprising:
a buffer layer on the substrate, wherein the buffer layer is disposed between the substrate and the GaN channel layer.

3. The GaN-based semiconductor device according to claim 2, wherein the buffer layer comprises AlN or GaN and has a thickness of about 3-5 μm.

4. The GaN-based semiconductor device according to claim 1, wherein the GaN channel layer has a thickness of 200-400 nm.

5. The GaN-based semiconductor device according to claim 1, wherein the AlGaN layer has a thickness of 10-14 nm.

6. The GaN-based semiconductor device according to claim 1, wherein the p-GaN gate layer has a thickness of 60-100 nm.

7. The GaN-based semiconductor device according to claim 1, wherein the gate electrode layer comprises a TiN bottom layer, a AlCu middle layer, and a TiN top layer, wherein the TiN bottom layer is in direct contact with the nitrogen-rich TiN hard mask layer.

8. The GaN-based semiconductor device according to claim 1, wherein the N/Ti ratio of the nitrogen-rich TiN hard mask layer is equal to or greater than 1.04.

9. The GaN-based semiconductor device according to claim 1 further comprising:
a Al₂O₃ passivation layer covering a sidewall of the p-GaN gate layer, a sidewall of the nitrogen-rich TiN hard mask layer, and a top surface of the AlGaN layer.

10. The GaN-based semiconductor device according to claim 9 further comprising:
an insulating layer disposed on the Al₂O₃ passivation layer.

11. A method for fabricating a GaN-based semiconductor device, comprising:
providing a substrate;
forming a GaN channel layer on the substrate;
forming a AlGaN layer on the GaN channel layer;
forming a p-GaN gate layer on the AlGaN layer;
forming a nitrogen-rich TiN hard mask layer on the p-GaN gate layer, wherein the nitrogen-rich TiN hard mask layer has a nitrogen-to-titanium (N/Ti) ratio that is greater than 1.0; and
forming a gate electrode layer on the nitrogen-rich TiN hard mask layer.

12. The method according to claim 11 further comprising:
forming a buffer layer on the substrate, wherein the buffer layer is disposed between the substrate and the GaN channel layer.

13. The method according to claim 12, wherein the buffer layer comprises AlN or GaN and has a thickness of 3-5 μm.

14. The method according to claim 11, wherein the GaN channel layer has a thickness of 200-400 nm, the AlGaN layer has a thickness of 10-14 nm, and the p-GaN gate layer has a thickness of 60-100 nm.

15. The method according to claim 11, wherein the nitrogen-rich TiN hard mask layer is formed on the p-GaN gate layer by sputtering at a direct current (DC) power that is equal to or greater than 4000 W.

16. The method according to claim 11, wherein the nitrogen-rich TiN hard mask layer is formed on the p-GaN gate layer by sputtering at a DC power of 7500-8500 W.

17. The method according to claim 11, wherein the gate electrode layer comprises a TiN bottom layer, a AlCu middle layer, and a TiN top layer, wherein the TiN bottom layer is in direct contact with the nitrogen-rich TiN hard mask layer.

18. The method according to claim 11, wherein the N/Ti ratio of the nitrogen-rich TiN hard mask layer is equal to or greater than 1.04.

19. The method according to claim 11 further comprising:
forming a Al₂O₃ passivation layer covering a sidewall of the p-GaN gate layer, a sidewall of the nitrogen-rich TiN hard mask layer, and a top surface of the AlGaN layer.

20. The method according to claim 19 further comprising:
forming an insulating layer on the Al₂O₃ passivation layer.
